(19) United States
(12) Patent Application Publication
(10) Pub. No.: US 2008/0135927 A1
(43) Pub. Date: Jun. 12, 2008

(54) SEMICONDUCTOR DEVICE AND MANUFACTURING METHOD THEREOF

(75) Inventors: Masaharu YAMAJI, Matsumoto City (JP); Naoto FUJISHIMA, Matsumoto City (JP); Mutsumi KITAMURA, Matsumoto City (JP)

Correspondence Address: ROSSI, KIMMS & McDOWELL LLP., P.O. BOX 826, ASHBURN, VA, 20146-0826, US

(73) Assignee: FUJI ELECTRIC DEVICE TECHNOLOGY CO., LTD., Tokyo (JP)

(21) Appl. No.: 11/944,355

(22) Filed: Nov. 21, 2007

(30) Foreign Application Priority Data
Nov. 22, 2006 (JP) 2006-315525

(51) Int. Cl. H01L 29/78; H01L 21/336

(52) U.S. Cl. 257/328; 438/237; 257/E29.262; 257/E21.429

(57) ABSTRACT

An insulated gate semiconductor device, specifically, a trench lateral MOSFET having improved hot carrier resistance can be provided without increasing the number of processes and device pitch and without degrading device breakdown voltages and on-resistance characteristics RonA. A junction depth Xj of a p base region of a TLPM (trench lateral power MOSFET) is made smaller than the depth of a trench, and the trench is formed with a depth Dt of about 1.2 μm such that the junction does not contact a curved corner part at the bottom of the trench.

### BACKGROUND

In markets such as the field of power supply ICs provided by integrating a lateral power MOSFET on a control circuit, strong demands for reducing power consumption and the size of power supply systems exist. To satisfy such demands, a further improvement is required in the efficiency and speed of power supply ICs. An index frequently used to represent such an improvement of efficiency is RonQg (represented in mΩmm²), which is the product of an on-resistance Ron of a MOS device and a gate charge Qg of the device. As will be understood from above, high efficiency in this context means that the ratio of energy lost for reasons other than the intended functions of the semiconductor, e.g., the heating of the semiconductor device, is kept small. That is, high efficiency means high utilization of energy with a small loss. A lateral power MOSFET for switching used in a power supply IC and the like has a greater loss attributable to the gate charge Qg of the same, and the higher the speed of the MOSFET. Therefore, both the on-resistance Ron and the gate charge Qg must be reduced to improve the efficiency of the device. Since the resistance at the channel region constitutes a large proportion of the on-resistance of a power MOSFET, reducing the channel resistance is also advantageous in reducing the entire on-resistance.

FIG. 9 is a sectional view of a lateral power MOSFET commonly used in the related art. In the lateral power MOSFET, a p base region 702 is formed on a surface of an n⁻ well layer 701 formed on a p substrate 700. An n⁺ source region 703 and a p⁺ contact region 708 are formed in the surface of the p base region 702. A source electrode 711 commonly connects to the surfaces of those regions. An n⁺ drain region 704 is formed on a surface of the n⁻ well layer 701 opposite to a gate electrode to sandwich a LOCOS oxide film 705 provided adjacent to the gate electrode, and a drain electrode 712 is provided in contact with the surface of the n⁺ drain region 704. A gate electrode 710 made of polycrystalline silicon is provided on the surface of the p base region 702, sandwiched between the surface of the n⁺ source region 703 and the surface of the n-well layer 701, with a gate oxide film 709 interposed between the electrode 710 and the surfaces of the regions 701, 702, 703. A voltage equal to or higher than an appropriate threshold voltage is applied to the gate electrode 710 to form an n-type inversion layer (hereinafter called a channel) 707 on the surface of the p base region 702 directly under the gate electrode 710, which provides a structure for establishing conduction between the drain electrode 712 and the source electrode 711.

In the lateral power MOSFET, the gate structure including the channel is formed parallel with the principal surface of the substrate. Although the device is therefore easy to manufacture, a problem arises in that the device tends to have a greater device cell pitch, which makes it difficult to achieve a low on-resistance. When the channel length or channel width is made smaller to achieve a smaller device pitch, the intensity of the electric field in the vicinity of the drain is increased when the device is turned on. Thus, the device becomes prone to a hot-carrier effect, namely acceleration of carriers (electrons) in the channel and injection of the same into the gate oxide film. The hot-carrier effect has negative impacts including variation of a gate threshold voltage Vth. A low concentration lightly doped drain (LDD) structure for relaxing electric field intensity is known as measures for suppressing such a hot-carrier effect.

The sectional view of FIG. 7-1 shows a trench lateral power MOSFET (which is sometimes abbreviated as TLPM) having a trench gate structure in which an n⁻ well layer 301 formed on the surface of a p⁻ semiconductor substrate 300 is vertically cut from the surface thereof to form a trench 311 and in which a gate electrode 310 is provided along the sidewall of the trench 311 with a gate oxide film 309 interposed therebetween. It is known that such structure provides a high channel density by reducing the device pitch and improving the degree of integration and that a lower on-resistance can therefore be achieved. To achieve further reductions in channel resistance and drain resistance, it has been attempted in the related art to achieve a lower RonA value (on-resistance per unit area) by making the depth of the trench 311 as small as possible to shorten the channel length.

Such a TLPM is also referred to as “high side n-channel TLPM.” The TLPM includes an n⁺ drain region 307 provided on a silicon substrate on one of the sidewalls of the trench 311 vertically formed from the surface of the n⁻ well layer formed on a low concentration p⁻-type semiconductor substrate 300, an n⁺⁺ region 305 formed on a surface of the n⁺ drain region 307, an n⁻ offset drain region 308 formed at the bottom of the trench, and drain metal electrodes 312 and 314 which are in contact with the n⁺⁺ region 305. It also includes a poly-silicon gate electrode 310 formed along another sidewall of the trench with the gate oxide film 309 interposed therebetween, a p base region 302 formed on the silicon substrate provided on the trench sidewall, and metal source electrodes 312 and 313 in contact with an n⁺ source region 303 and a p⁺ region 304 formed in the surface of the p base region 302. The degradation of characteristics attributable to the generation of hot carriers, however, can still occur in such TLPMs when the length of overlap between the gate electrode 310 on the trench sidewall and the drain region is reduced in an attempt to reduce the gate charge Qg.

Japanese Unexamined Patent Application Publication No. 10-74945 (corresponding U.S. Pat. No. 5,877,532 and U.S. Pat. No. 6,261,910) discloses a structure for improving hot carrier resistance, i.e., an LDD (lightly doped drain) structure provided only on the drain side of a trench type lateral MOSFET. According to this reference, an LDD structure is provided only on the drain side of a lateral MOSFET having a trench structure to improve the hot carrier resistance. However, since a spacer is used for forming the LDD layer, new problems arise including an increase in the number of processes, an increased device pitch, and an increased on-resistance RonA.

In the case of the TLPM shown in FIG. 7-1, the structure employing the trench gate provided on the trench sidewall makes it difficult to use an LDD structure for suppressing hot carriers as described above. As a result, the device is prone to the degradation of hot carrier resistance, which is in a trade-off relationship with the reduction in the on-resistance RonA.

Accordingly, there remains a need for a semiconductor device, in particular an insulated gate semiconductor device, i.e., a trench lateral MOSFET, having improved hot carrier resistance without increasing the number of processes and the device pitch, and without degrading the breakdown voltage characteristics and the on-resistance RonA characteristics of the device. The present invention addresses this need.

### SUMMARY OF THE INVENTION

The present invention relates to semiconductor devices and a method of manufacturing thereof. In particular, the present invention relates to semiconductor devices that include insulated gate semiconductor devices for switching such as DC-DC converter ICs having middle class breakdown voltages Vcc in the range from 5 to 15 V, where high efficiency, high-speed capability, high reliability and the like are required.

One aspect of the present invention is a semiconductor device comprising a semiconductor substrate of a first conductivity type, a low concentration well layer of a second conductivity type on the substrate, a trench formed in a main surface of the well layer, a base region of the first conductivity type in the well layer, a source region of the second conductivity type on a main surface of the base region, and a high concentration drain region of the second conductivity type in the well layer.

The trench can have sidewalls with at least one of the sidewalls having a substantially vertical portion that is substantially vertical to the main surface of the well layer and a curved corner portion extending from the substantially vertical portion and joining the bottom of the trench. The gate electrode extends along the one sidewall of the trench with a gate oxide film interposed therebetween. The base region and the well layer form a p-n junction. The base region is in contact with the gate oxide film on the one sidewall of the trench and an end of the p-n junction is positioned at the substantially vertical portion of the one sidewall, at a position shallower than the curved portion. The source region on the main surface of the base region is in contact with the gate oxide film on the one sidewall of the trench. The high concentration drain region is on the side of another sidewall of the trench opposite to the one sidewall of the trench.

The well layer has a region having a surface concentration of at least 1.0×10¹⁷/cm³. The region having a surface concentration of at least 1.0×10¹⁷/cm³ can be an offset drain region of the second conductivity type in the well layer at the bottom of the trench and spaced from the base region. Alternatively, the well layer can be an epitaxial layer and the region having a surface concentration of at least 1.0×10¹⁷/cm³ can be the epitaxial layer. The offset drain region or the epitaxial layer has a surface concentration of no greater than 2.0×10¹⁷/cm³. The offset drain region and the high concentration drain region can be connected.

The device can further include a field plate on the another sidewall of the trench with an oxide film interposed therebetween, and a drain electrode conductively connected to the high concentration drain region. The field plate is conductively connected to the drain electrode.

The device can further include a source electrode conductively connected to the source region, and a high concentration region of the first conductivity on the main surface of the base region and in contact with the source region, and an insulation film embedded in the trench. The source electrode also is conductively connected to the high concentration region of the first conductivity.

Another aspect of the present invention is a method of manufacturing the above described semiconductor device. The method can include providing the semiconductor substrate, forming the low concentration well layer, the trench in the main surface of the well layer with the substantially vertical portion and the curved corner portion extending from the substantially vertical portion and joining a bottom of the trench, the gate electrode extending along the one sidewall of the trench with the gate oxide film interposed therebetween, the base region in the well layer to form a p-n junction with the well layer, and so that the base region is in contact with the gate oxide film on the one sidewall of the trench and the end of the p-n junction is positioned at the substantially vertical portion of the one sidewall, at a positioned shallower than the curved portion, the source region on the main surface of the base region and in contact with the gate oxide film on the one sidewall of the trench, and the high concentration drain region in the well layer on the side of another sidewall of the trench opposite to the one sidewall of the trench. The well layer has the region with a surface concentration of at least 1.0×10¹⁷/cm³.

The method can further include the step of forming the offset drain region in the well layer at the bottom of the trench and spaced from the base region. The offset drain region is the region having a surface concentration of at least 1.0×10¹⁷/cm³ but not greater than 2.0×10¹⁷/cm³.

The well layer can be an epitaxial layer and the region having a surface concentration of at least 1.0×10¹⁷/cm³ comprises the epitaxial layer, but not greater than 2.0×10¹⁷/cm³.

### BRIEF DESCRIPTION OF THE DRAWINGS

FIG. 1 is a sectional view of major parts of one embodiment of a TLPM according to the present invention.

FIG. 2 is a graph showing the relationship between breakdown voltages, the trench depth Dt, and the on-resistance RonA of the TLPM.

FIG. 3 is a graph showing the relationship between the rate of variation of drain on-current Ion attributable to DC stress and offset drain surface concentration Nd observed in the TLPM.

FIG. 4 is a graph showing the rates of variation of the drain on-current Ion and a threshold voltage Vth of the TLPM.

FIG. 5 is a sectional view showing a high electric field region in the vicinity of a trench gate of the TLPM.

FIG. 6 is a graph showing the relationship between the breakdown voltages, the Ion variation rate, and the offset drain surface concentration Nd of the TLPM.

FIG. 7-1 is a sectional view of major parts of a TLPM according to the related art.

FIG. 7-2 is a sectional view of major parts of another embodiment of the TLPM according to the present invention.

FIG. 8 is a sectional view of major parts of another embodiment of the TLPM according to the present invention.

FIG. 9 is a sectional view of major parts of an LDMOS according to the related art.

FIG. 10 is a sectional view of major parts of the TLPM according to the embodiment of FIG. 7-2 showing a self-aligning process thereof.

FIGS. 11A, 11B, and 11C are graphs showing the relationship between the on-state breakdown voltage and the drain current in the embodiment of FIG. 7-2 using the trench depth Dt as a parameter.

FIG. 12 is a graph showing the relationship between the on-state breakdown voltage and RonQg in the embodiment of FIG. 7-2 using the trench depth Dt as a parameter.

FIG. 13 is a sectional view of major parts of the TLPM according to the embodiment of FIG. 7-2 for explaining a capacitance Cgd across the gate and the drain thereof.

FIG. 14 is a graph showing the result of measurement of a base current Ib of the TLPM according to the embodiment of FIG. 7-2.

FIGS. 15A and 15B illustrate electric field distributions in the TLPM according to the embodiment of FIG. 7-2 and an LDMOS calculated based on device simulations at a gate voltage Vg of 2 V and a drain voltage Vd of 15 V.

FIG. 16 is a graph showing variations of characteristics of the TLPM according to the embodiment of FIG. 7-2 attributable to DC stress (Vd=15 V, Vg=2 V) at the trench depth Dt of 0.7 μm.

FIGS. 17A and 17B illustrate distributions of impact ionization rates in the vicinity of the trench gate of the TLPM according to the embodiment of FIG. 7-2 based on device simulations where Vg=2 V and Vd=15V and carried out at a trench depth Dt of 1 μm (FIG. 17A) and a trench depth Dt of 0.7 μm (FIG. 17B).

FIG. 18 is a graph showing the relationship between the breakdown voltage and RonQg of the TLPM according to the embodiment of FIG. 7-2.

### DETAILED DESCRIPTION

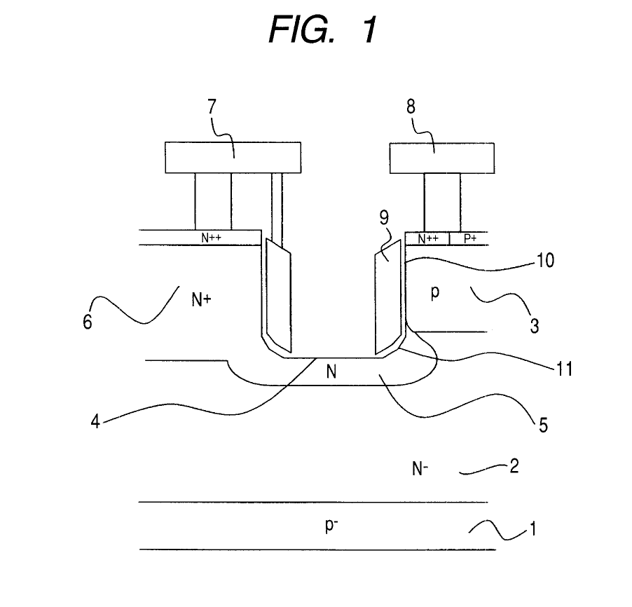

Referring to FIG. 1, which shows a sectional view of one embodiment of a TLPM (trench lateral power MOSFET) according to the present invention, during major manufacturing processes, a diffusion process is first selectively performed in a p⁻ substrate 1 to form a deep n⁻ well layer 2 having a junction depth Xj of 3 to 4 μm, and boron in a dose of 3×10¹³/cm² is ion-implanted in the region on the source side of the TLPM. Thereafter, an anisotropic etching or a trench etching process can be performed through an oxide film mask (not shown) to form a trench 4. At this time, the shape of the bottom of the trench 4 includes curved portions, as shown in FIG. 1, which are attributable to the difference between etching rates at end portions of the trench and at a middle portion thereof. The bottom of the trench 4 is further rounded by a subsequent CDE (chemical dry etching) process, which exhibits the nature of isotropic etching, and the curved portions extend in the vertical direction to a height of about 0.3 μm from the bottom of the trench 4. The depth of the trench 4 formed is 1.2 μm. Then, buffer oxidation treatment is performed on the inner surface of the trench 4. Next, phosphorous is ion-implanted in a dose ranging from 1×10¹⁷/cm² to 2×10¹⁷/cm² to the bottom of the trench 4 in a direction perpendicular to a principal surface of the substrate using the oxide film mask used for forming the trench as described above. Subsequently, a thermal diffusion process is carried out to form a p base region 3 having a junction depth Xj of about 1.1 μm, and an n⁻ offset drain layer 5 having a junction depth Xj of about 1.0 μm at the same time through diffusion. Thereafter, to achieve a low on-resistance, an n⁺ drain layer 6 having a greater depth Xj of about 1.2 μm and a high concentration is formed on the drain side using ion implantation at a high acceleration voltage, whereby drain resistance components are minimized.

Thereafter, a high concentration n⁺ layer and a high concentration p⁺ layer are formed on surfaces of the drain and source regions to reduce the contact resistance between each of the regions and a metal electrode, and the drain region and the source region are coated with a drain electrode 7 and a source electrode 8, respectively. Referring now to gate electrodes 9, after a gate oxide film 10 is formed, a conductive poly-silicon is deposited thereon. The poly-silicon is patterned through anisotropic etching to provide a poly-silicon electrode on each of the opposing sidewalls in the trench 4 facing each other with gate oxide films 9 interposed between them.

Referring to the two poly-silicon gates, the poly-silicon gate deposited on the drain side is not used as a gate electrode. Rather, it is configured to be always shorted with the drain electrode. The TLPM according to FIG. 1 is completed through the above-described flow of processes. The junction depth Xj of the p base layer 3 is smaller than the depth Dt of the trench 4. It is important that the p-n junction of the p base region 3 is curved with roundness such that the junction meets the sidewall above the curved portion 11 at the bottom of the trench 4 instead of meeting at the curvature, the curve being formed as a result of conversion of the p base region into the n-type, which occurs in the vicinity of the curved portion 11 because the concentration profile of the n⁻ offset drain layer 5 formed at the bottom of the trench 4 spreads into the curved portion 11 of the trench 4 due to lateral diffusion of the same.

In this embodiment, the trench 4 has a width Lt of 1.2 μm and a trench depth Dt of 1.2 μm; the part of the p base region meeting the trench sidewall has a junction depth Xj of 0.9 μm; and the source n⁺ layer has a junction depth Xj of 0.25 μm. That is, the effective channel length is approximately 0.90−0.25=0.65 μm. The thickness of the gate oxide film is about 17 nm. The surface concentration Nd of the n⁻ offset drain layer 5 is preferably 1.0×10¹⁷/cm³ or more, and there is an upper limit of 2.0×10¹⁷/cm³ for the same when the on-state breakdown voltage BVon is 15 V or more.

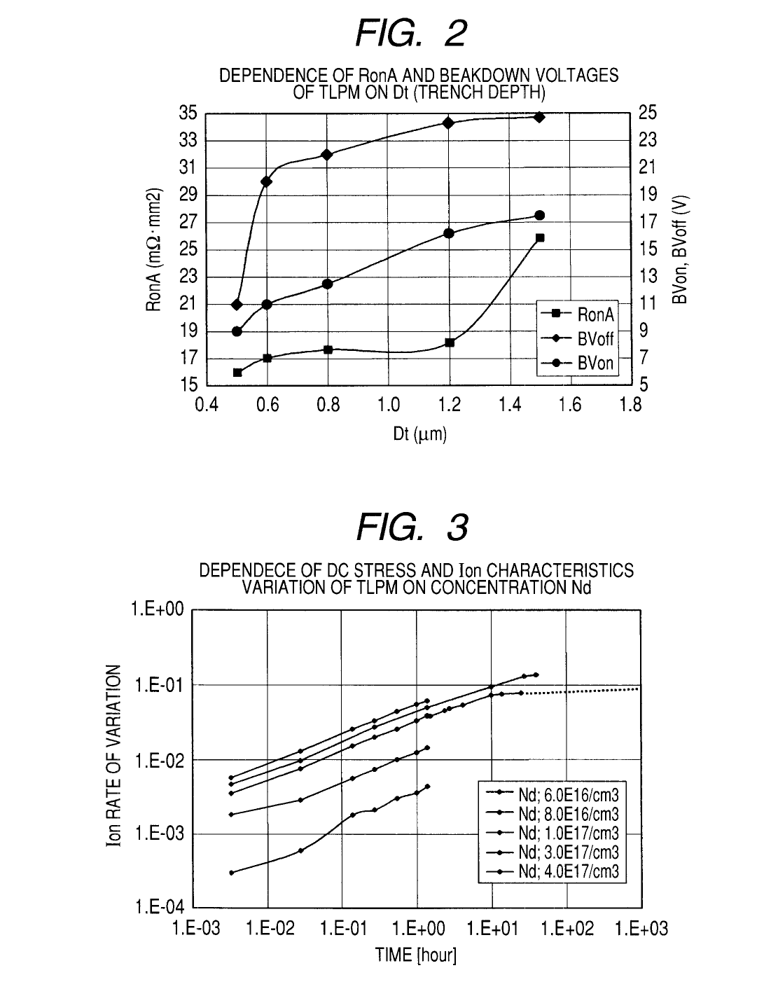

FIG. 2 shows a graph on which the relationship between the on-state breakdown voltage BVon (ordinate axis), the off-state breakdown voltage BVoff (ordinate axis), and the on-resistance RonA (ordinate axis) of the TLPM is plotted using the trench depth Dt (abscissa axis) as a parameter. As shown in FIG. 2, the n⁻ offset drain region at the bottom of the trench becomes greater in the depth direction and therefore has a greater total length, the greater the trench depth Dt plotted along the abscissa axis. Thus, the drain resistance is increased, and the on-resistance RonA is degraded. When the trench depth is made smaller, the p base region contacts the curvature part at the bottom of the trench. As a result, an increased current flows through the substrate in the on-state to decrease the on-state breakdown voltage. In the off-state, the smaller depth results in a punch-through effect, which decreases the off-state breakdown voltage. FIG. 2 shows that both the on-state breakdown voltage BVon and the off-state breakdown voltage BVoff are kept at 15 V or more to establish a satisfactory trade-off between the breakdown voltages and the on-resistance RonA when the trench depth Dt is 1.1 μm to 1.2 μm.

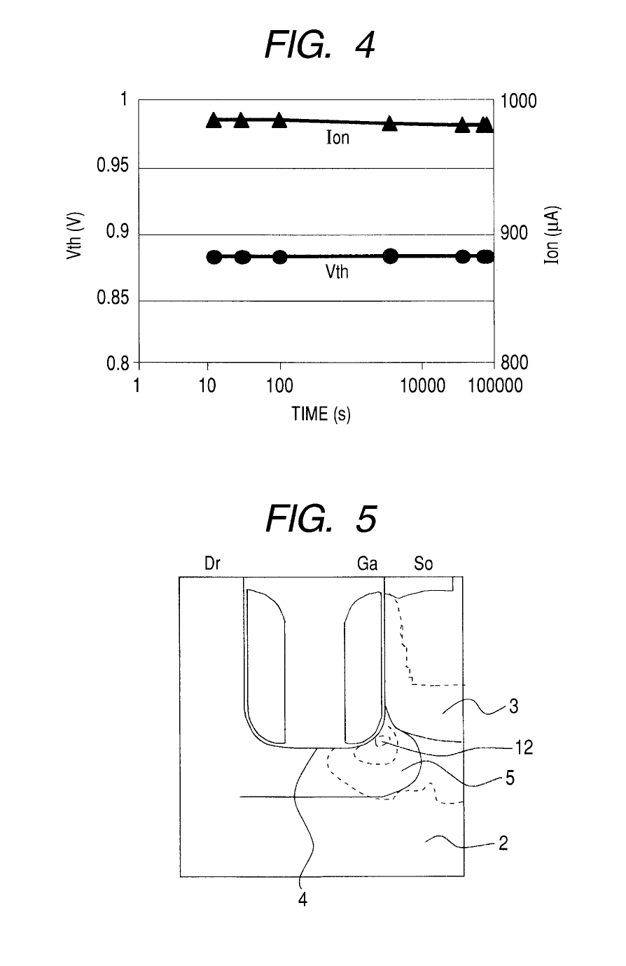

A hot carrier test was conducted on the TLPM with the trench depth Dt set at 1.2 μm using the n⁻ offset drain surface concentration Nd as a parameter. A DC stress bias was imparted by applying a gate voltage Vg of 2.0 V at which the TLPM had a peak substrate current at an ambient temperature of 25° C. and applying a drain voltage Vd of 15 V to allow the device to be usable at a rated voltage of 15 V. Referring to the failure specifications for the hot carrier resistance test, variation of 10% was defined as a failure for both of the threshold voltage Vth and the drain on-current Ion. FIGS. 3 and 4 show results of the test. FIG. 3 is a relational diagram showing the dependence of the drain on-current Ion on the n⁻ offset drain surface concentration Nd identified by the hot carrier test on the TLPM. The abscissa axis represents time, and the description “1.E−03” means “1.0×10⁻³”. Other similar descriptions have similar meanings. The ordinate axis represents the rate of variation of the drain on-current Ion (μA). FIG. 4 is a relational diagram similarly showing variation of the characteristics of the drain on-current Ion and the threshold voltage Vth that occurred when DC stress was imparted to the TLPM. The abscissa axis represents time (S) and the ordinate axis represents threshold voltage Vth (V) and the drain on-current Ion (μA).

As shown in FIGS. 3 and 4, the threshold voltage Vth of the TLMP device undergoes variation of 1% or less (a few millivolts) or substantially no variation even when ten hours are spent under the DC stress. However, since the drain on-current Ion undergoes significant variation, the device must be optimized to cope with the variation of the drain on-current Ion. As will be understood from FIG. 3, the hot carrier resistance of this device has dependence on the n⁻ offset drain surface concentration Nd, and the drain on-current Ion decreases substantially by 10% when the device spends ten hours under the DC stress at the n⁻ offset drain surface concentration Nd of 8.0×10¹⁶/cm³. However, when the n⁻ offset drain surface concentration Nd is as high as 1.0×10¹⁷/cm³, the amount of variation begins saturating after ten hours are spent under the DC stress. An extrapolation line indicating 1000 hours for the drain on-current Ion to be decreased by 10% can be drawn from such saturation of the amount of variation of the drain on-current Ion.

A description will now be made on the mechanism of degradation of the drain on-current Ion characteristics of the device attributable to the injection of hot carriers. For the purpose of description, FIG. 5 shows a sectional view illustrating how impact ionization proceeds in the on-state of the TLPM whose trench 4 has a depth Dt of 1.2 μm. In the sectional view of FIG. 5, an inner small loop 12 among the looped curves shown in broken lines in the vicinity of the curved portion 11 at the bottom of the trench 4 represents an electric field region having the highest intensity. The high electric field region is a region that is prone to the generation of hot carriers at a high concentration. When the TLPM is in the on-state, electrons of electron-hole pairs generated in the high electric field region 12 in the vicinity of the gate oxide film of the n⁻ offset drain layer 5 are trapped into the gate oxide film while being multiplied by the avalanche effect. At this time, since the n⁻ offset drain layer 5 is depleted to compensate for surface charges of the layer with donors, and the drain resistance consequently increases to degrade the drain on-current Ion. However, when the surface concentration Nd of the n⁻ offset drain is as high as 1.0×10¹⁷/cm³, the depletion of the n⁻ offset drain layer 5 of the TLPM is suppressed, and the increase in the drain resistance also can be suppressed. Therefore, the reduction of the on-state current is also suppressed, and the saturation of the amount of variation in the drain current Ion occurs as indicated by the line in FIG. 3 plotted when the n⁻ offset drain surface concentration Nd as a parameter is 1.0×10¹⁷/cm³. When the n⁻ offset drain surface concentration Nd is higher than 1.0×10¹⁷/cm³, the depletion on the surface of the n⁻ offset drain layer is further suppressed, and the amount of variation in the drain on-current Ion is also suppressed further.

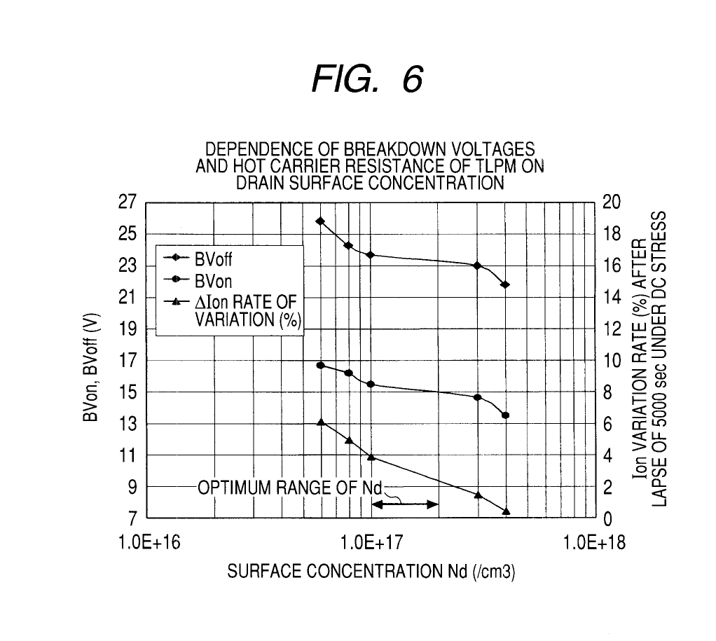

FIG. 6 shows a graph indicating the relationship between the breakdown voltages, the amount of variation in the drain-on current Ion, and the offset drain surface concentration Nd of the TLPM. The description “5.0E+16” shown along the abscissa axis means “5.0×10¹⁶”. Other similar descriptions have similar meanings. As described above, when the n⁻ offset drain surface concentration Nd is as high as 1.0×10¹⁷/cm³ or more, the hot carrier resistance is improved. However, the surface concentration Nd of the n⁻ offset drain layer is a parameter that also affects the breakdown voltages of the TLPM. FIG. 6 indicates that as both the on-state breakdown voltage and the off-state breakdown voltage become smaller, the higher the n⁻ offset drain surface concentration Nd. Further, when the n⁻ offset drain surface concentration Nd is as high as 2.0×10¹⁷/cm³ or more, the on-state breakdown voltage falls below the rated voltage of 15 V. Therefore, to achieve the required breakdown voltage characteristics, i.e., the on-state breakdown voltage of 15 V, the device is limited to the condition where the n⁻ offset drain surface concentration Nd is not lower than 1.0×10¹⁷/cm³ and not higher than 2.0×10¹⁷/cm³. Thus, in a TLPM device configured according to the condition where the trench depth Dt is 1.2 μm and where the n⁻ offset drain layer surface concentration Nd is not lower than 1.0×10¹⁷/cm³ and not higher than 2.0×10¹⁷/cm³, improved hot carrier resistance can be achieved while satisfying required breakdown voltage characteristics and low on-resistance RonA characteristics when the on-state breakdown voltage rating is specified as 15 V.

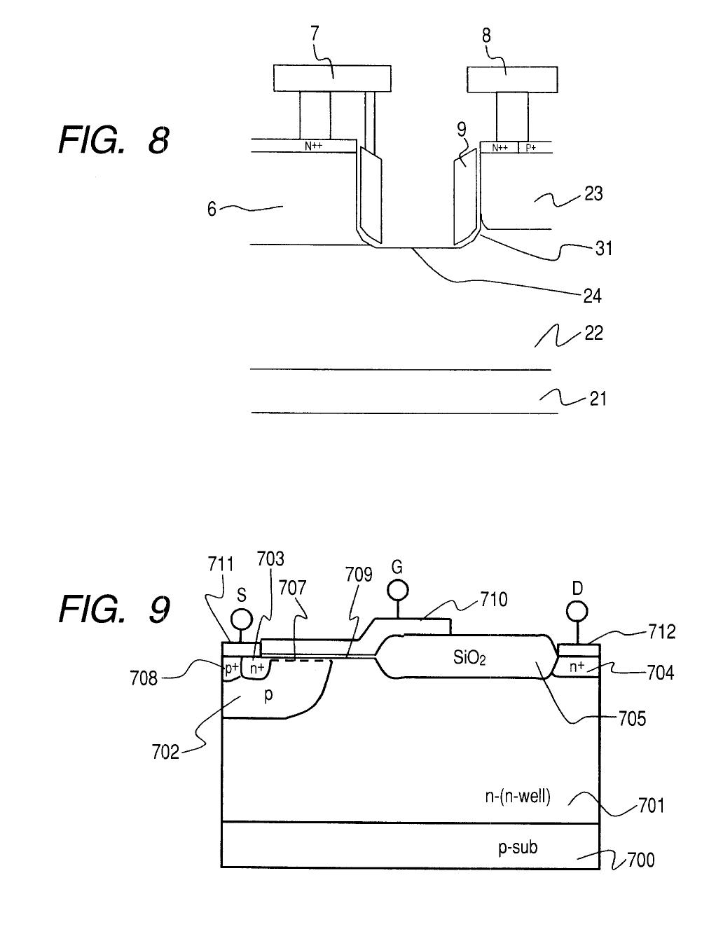

As described above, the junction depth Xj of the p base region of the TLPM is made smaller than the trench depth, and the trench is formed with a trench depth Dt of about 1.2 μm such that the p base region does not contact the curvature part at the bottom of the trench. Thus, the TLPM device meets the on-state and off-state breakdown voltage rating of 15 V and satisfies the requirement for a low on-resistance RonA. Since the n⁻ offset drain layer is formed to have a surface concentration Nd in the range from 1.0×10¹⁷/cm³ to 2.0×10¹⁷/cm³, the influence of the injection of hot carriers (electrons in this case) on the on-state current is reduced at a point where an electric field concentrates. Thus, the degradation of characteristics (the degradation of drain on-current Ion in this case) attributable to hot carriers can be dramatically mitigated. Referring to FIG. 8, which illustrates another embodiment of a TLPM according to the present invention, an n⁻ epitaxial layer 22 is deposited on a p⁻ substrate 21. Here, the well layer can be an n⁻ epitaxial layer 22 having a deep junction without the n⁻ offset drain layer 5 incorporated in FIG. 1. The n⁻ epitaxial layer 22 is provided with a surface concentration in the range from 1.0×10¹⁷/cm³ to 2.0×10¹⁷/cm³. Boron is ion-implanted on the surface of the n⁻ epitaxial layer 22 to form a p base region 23. Anisotropic trench etching is then performed to form a trench 24. Thermal diffusion is carried out to form the p base region 23. At this time, the point where the junction of the p base region 23 meets the sidewall of the trench 24 should not be located in a curvature part 31 at the bottom of the trench. The device is formed with a configuration that is otherwise similar to that shown in FIG. 1, which makes it possible to achieve the effect of improving hot carrier resistance in the same manner as in the embodiment of FIG. 1.

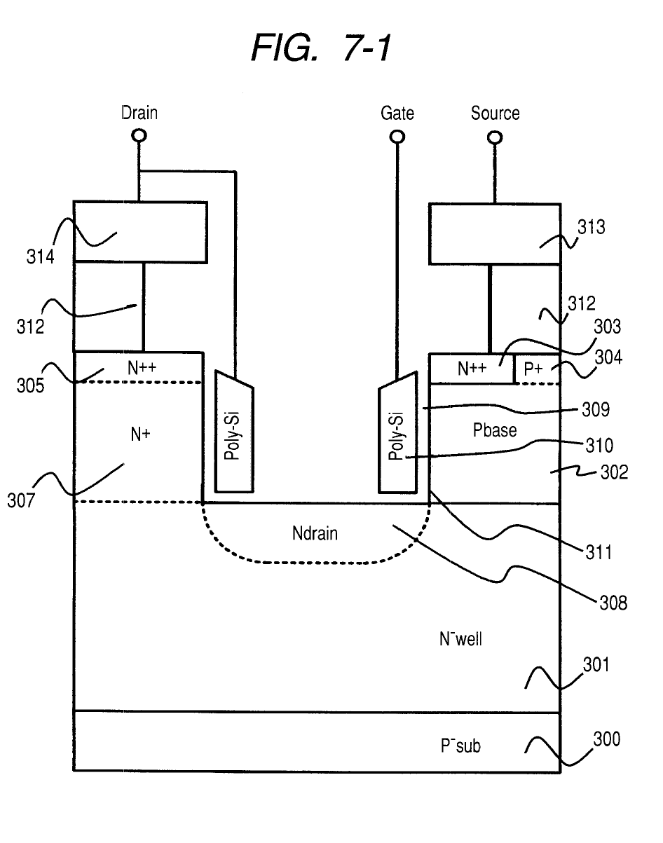

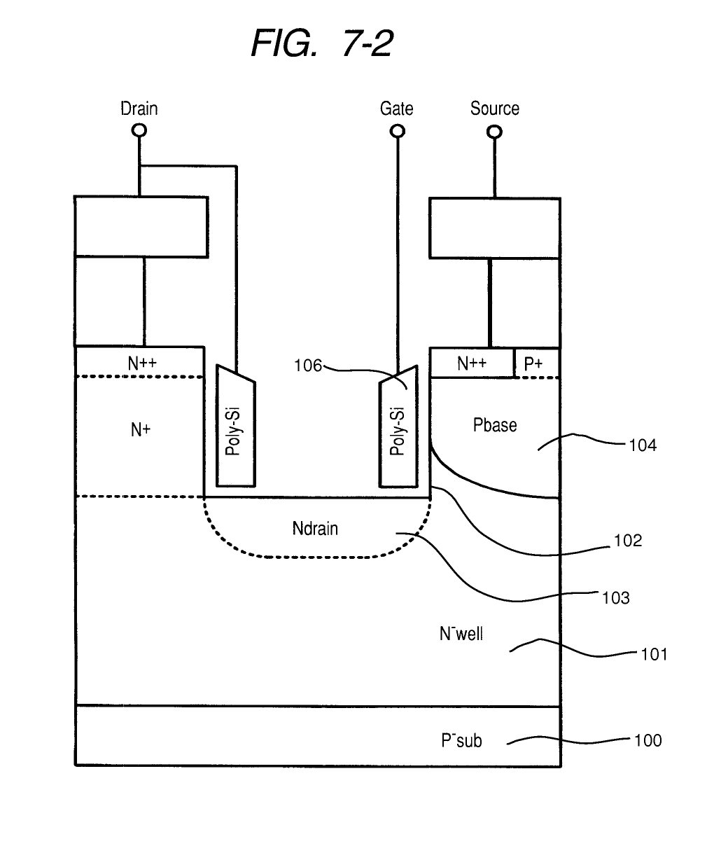

Referring to FIG. 7-2, which shows another embodiment of a TLPM, similar to the embodiment of FIG. 7-1, in that the gate is formed on the sidewall of a trench to provide a small device pitch, which allows a low on-resistance to be achieved. Further, since the gate region and the drain region are formed using manufacturing processes according to the trench self-alignment method, there is no need for a mask margin as seen in the LDMOS shown in FIG. 9, which has a structure according to the related art. Accordingly, an overlap between the gate and the drain can be made small to allow switching at a high speed. Further, since the device can be fabricated by adding only two photolithographic steps required for the trench and the trench gate to a CDMOS process according to the related art, the cost can be reduced. Therefore, the device can be advantageously used as an output-stage element to be incorporated in a high-speed and high-efficiency DC-DC converter IC.

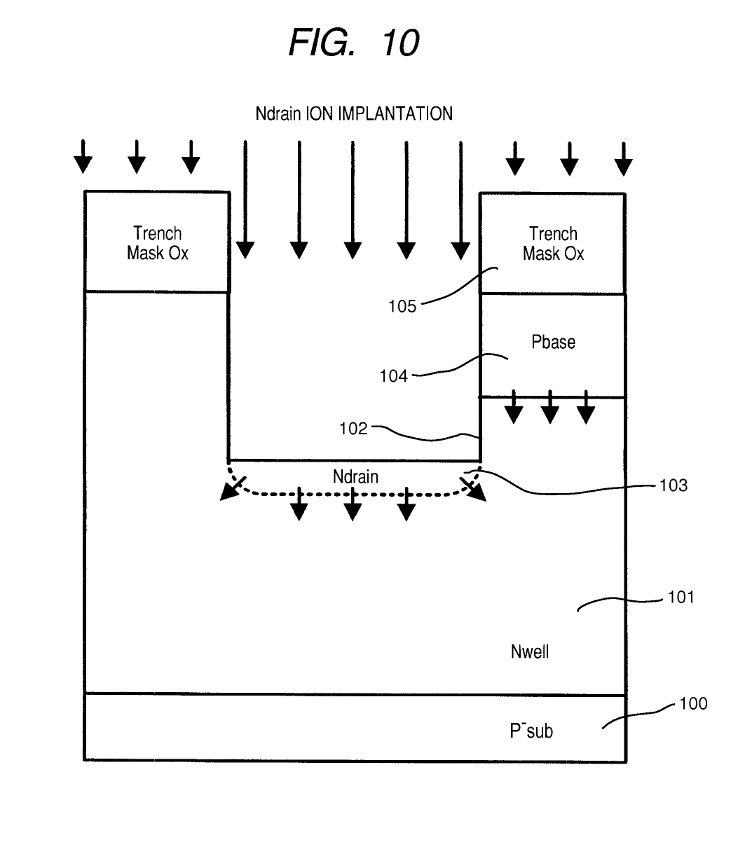

The TLPM manufacturing process according to the embodiment of FIG. 7-2 now follows. This example is a version of a process for 0.6 μm CDMOS devices covering a TLPM as an optional device. One feature of this manufacturing process is as follows. As shown in FIG. 10, anisotropic etching is performed to form a trench 102 in a semiconductor substrate that has been obtained by ion-implanting boron to form an n⁻ well layer 101 and a p base region in a p⁻ substrate 100. Thereafter, phosphorous is ion-implanted at the bottom of the trench 102 with masking provided by using a trench mask oxide film 105 as present, and then thermal diffusion is performed to form an n⁻ offset drain region 103 and a p base region 104. Thus, the n⁻ offset drain region 103 can be formed on a self alignment basis. In the case of the LDMOS shown in FIG. 9, although the source and base regions can be formed on a self alignment basis by masking the gate electrode, mask alignment must be separately performed to form the drain region before forming the gate electrode. In the TLPM shown in FIG. 7-2, since the n⁻ offset drain region 103 and the gate electrode 106 are formed on a self alignment basis using the trench, there is no particular need for masking alignment. In the case of the LDMOS shown in FIG. 9, the device pitch must be increased to optimize the gate length. In the TLPM of FIG. 7-2, since the gate length can be adjusted by the trench depth, no change is made in the device pitch, which is advantageous in achieving the low on-resistance. The gate electrode 106 of the TLPM can be formed at the same deposition step at which a CMOS and a DMOS are formed on the same semiconductor substrate. However, the gate requires a separate etching step because of its difference from the CMOS gate in precision. Since the TLPM of FIG. 7-2 can be fabricated by simply adding two photolithographic steps required for the trench and the trench gate to a normal CDMOS process, the device is advantageous in terms of cost in applications requiring an incorporated low-resistance power MOS.

FIG. 7-2 shows the TLPM having an absolute maximum rated voltage of 15 V. Major process parameters that determine device characteristics such as the breakdown voltage BV, on-resistance per unit area RonA, and threshold voltage Vth are as follows:

trench width (Lt): BV, RonA,

trench depth (Dt): BV, RonA,

n⁻ offset drain concentration (dose): BV, RonA, and

p base concentration (dose): Vth.

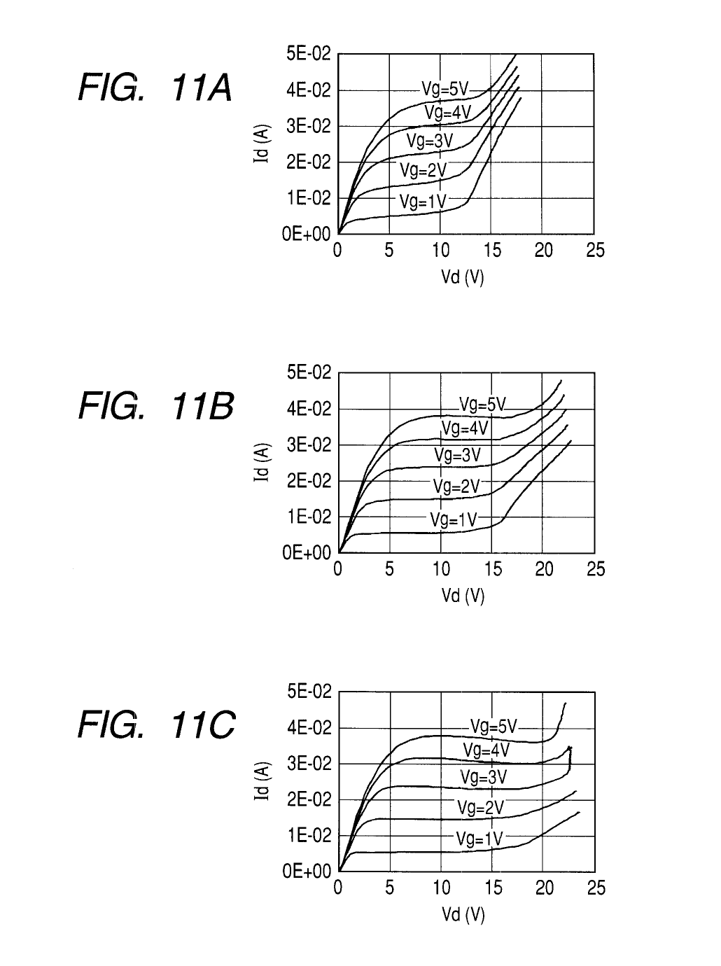

Parameters specific to the TLPM are the trench width Lt, trench depth Dt, and n-offset drain concentration. Other parameters such as those for ion implantation are commonly used for the TLPM, the CMOS, the DMOS, and a bipolar transistor. The trench depth Dt is represented by the ratio of the same to an optimum depth that is assumed to be 1. FIGS. 11A, 11B, and 11C show on-state breakdown voltages resulting from various trench depths Dt. FIGS. 11A, 11B, and 11B are graphs showing relationships between on-state breakdown voltages BVon and drain currents Id at the trench depth Dt of 0.7 μm, 1.0 μm, and 1.3 μm, respectively. The on-state breakdown voltage (Vg>Vth: a breakdown voltage in the on-state) significantly depends on the trench depth Dt, and it does not reach the absolute maximum rating of 15 V at the trench depth Dt of 0.7 μm. The TLPM has a corner, which can be curved, on the bottom of the trench. When the region of contact between the p base and the trench is located at the corner, such as illustrated in the embodiment of FIG. 7-1, an electric field having a higher intensity is formed in the vicinity of the end of the gate on the source side of the drain region. When the trench depth Dt is made greater and the region of contact between the p base and the trench consequently moves away from the corner such that the region of contact is located only on the substantially vertical portion of the sidewall, such as shown in FIG. 7-2, the electric field is relaxed to increase the on-state breakdown voltage. The TLPM can be integrated in a power IC as a device at an output stage thereof, but must have low gate charge characteristics RonQg to maintain high efficiency even when switching takes place at a high frequency.

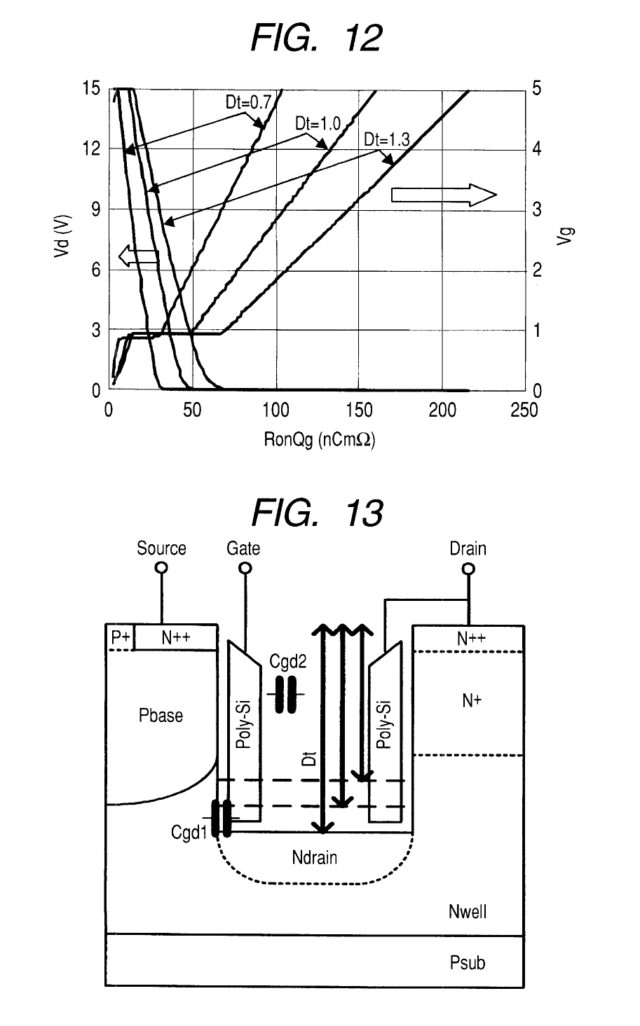

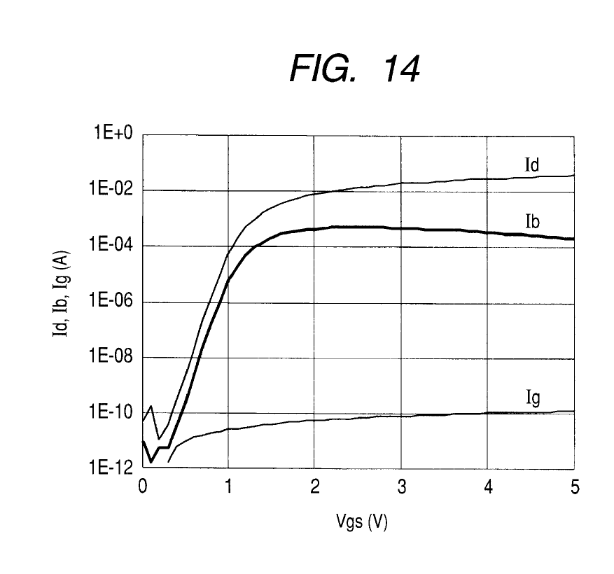

FIG. 12 shows gate charge characteristics RonQg resulting from various trench depths Dt. RonQg is an index that is commonly used to indicate switching characteristics. FIG. 12 shows that as the RonQg value becomes smaller to provide good switching characteristics, the smaller the trench depth Dt is needed. The reason is that the different trench depths Dt result in different drain-gate overlap amounts and consequently provide different gate-drain capacitances Cgd (FIG. 13). It is apparent from above that there is a trade-off relationship between the on-state breakdown voltages and the gate charge characteristics RonQg.

### (Hot Carrier Resistance)

### (1) Base (Substrate) Current

In general, deterioration attributable to hot carriers is known from the fact that the problem of variation in threshold voltage Vth and mutual conductance (gm) of MOS devices occurs because the reduction of power supply voltage is not achieved to keep pace with the trend toward finer MOS devices. In this regard, attention must be paid especially to high-breakdown-voltage MOSFETs that operate on a high power supply voltage and that are repeatedly turned on/off at a high speed when used as a switching element.

The mechanism of the generation of hot carriers is generally known as follows. Impact ionization occurs in a high electric field at the drain side of the device to generate electron-hole pairs. Part of electrons having high energy thus generated are injected into the gate oxide film and entrapped therein to cause variation of the threshold voltage Vth and the like. Almost all holes generated as a result of impact ionization constitute a base (substrate) current Ib. The conditions that result in the highest electric field can be identified by measuring the base current Ib. In the case of the present TLPM, the base current is measured instead of the current that flows through the substrate because it is a high-side switching device.

FIG. 14 shows results of measurement of the base current Ib of the TLPM of the embodiment of FIG. 7-2. Referring to the condition of measurement, Vd=15V, and Vs=Vsub=0 V. The description “1E−12” shown along the ordinate axis means “1×10¹²”. Other similar descriptions have similar meanings. FIG. 14 shows the base current Ib along with the drain current Id and the gate current Ig. It is generally known that the substrate current Ib is at the maximum when Vg=Vd/2 in the case of a planar device (a device such as a normal n-channel MOSFET or n-channel DMOSFET in which current flows on the surface of the substrate thereof). In the present TLPM, as shown in FIG. 14, the base current Ib is at the maximum where Vg=2.5 V=Vd/6 when Vd=15V.

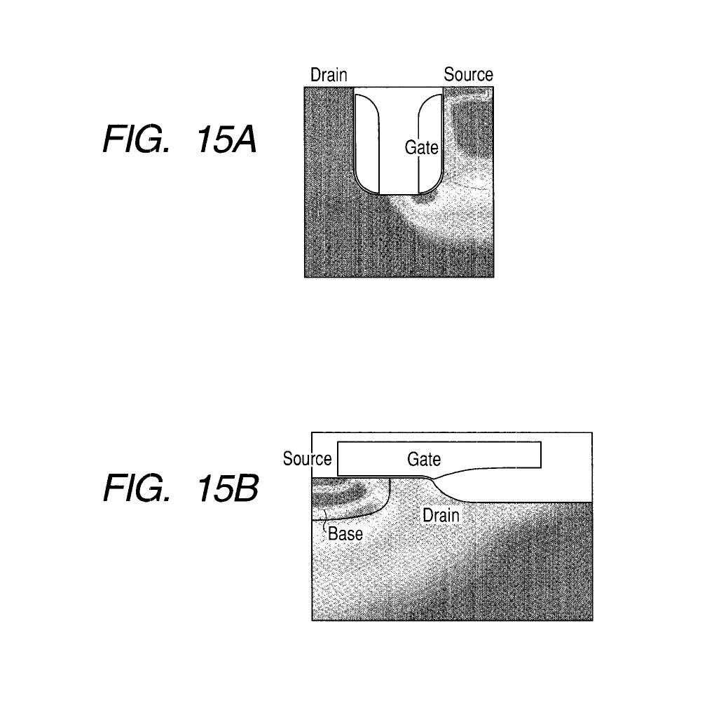

FIGS. 15A and 15B show distributions of electric fields in the TLPM (FIG. 15A) and a DMOS (FIG. 15B) calculated based on device simulations carried out at Vg=2 V and Vd=15V. In the DMOS, the current path is curved in the direction of relaxing the electric field in the LOCOS region. In the TLPM, the current path is curved in the direction of increasing the electric field intensity at the bottom of the trench. However, the electric field is relaxed when the gate voltage Vg increases because the potential distribution spreads toward the drain. Therefore, the TLPM has low dependence on the drain voltage because of its difference in structure from a planar device having no trench, and the base current Ib is at the maximum when the gate voltage is low (2 to 3 V).

### (2) Hot Carrier Resistance

FIG. 4 shows variation of the characteristics of the TLPM that occurs when DC stress (Vd=15 V, Vg=2 V) is applied to the same. It will be understood that substantially no variation occurs in the drain on-current Ion and the threshold voltage Vth during 10000 seconds.

### (3) Relationship Between Hot Carrier Resistance and Trench Depth Dt

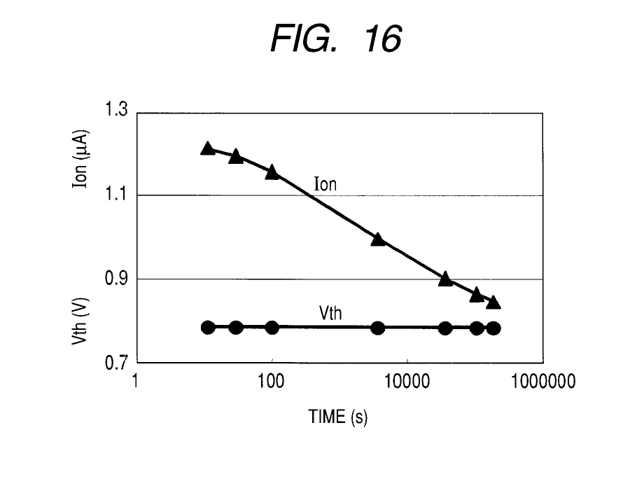

It is assumed that hot carrier resistance is small when the trench depth Dt is 0.7 μm because the on-state breakdown voltage abruptly dropped at that depth. FIG. 16 shows variation of characteristics under the DC stress (Vd=15 V, Vg=2 V) at the trench depth Dt of 0.7 μm. Substantially no variation occurred in both of the threshold voltage Vth and the drain current Ion when the trench depth Dt was 1 μm. At the trench depth Dt of 0.7 μm, substantially no variation occurred in the threshold voltage Vth, whereas the drain on-current Ion significantly decreased.

The reason for the above follows. It is generally known that impact ionization occurs at a high rate in the region where an intense electric field exists to generate electron-hole pairs and that part of the electrons having high energy thus generated are entrapped in a gate oxide film. In a planar device such as an NMOSFET having no trench, a high electric field is generated at an end of the drain in the channel region. In the TLPM having a trench gate structure, a high electric field is generated at an end of the channel in the drain region as described above.

Since the channel region of an NMOSFET is parallel to the surface of the Si substrate, the impurity has a uniform concentration. Therefore, when the gate oxide film entraps hot electrons to hold fixed electric charges therein, variation of the threshold voltage Vth occurs. In the case of the TLPM according to the invention, since the channel region (p base region) is formed by ion-implanting boron from the surface of the Si substrate and thermally diffusing the same in the depth direction, impact ionization occurs at a higher rate to generate hot electrons in the vicinity of the bottom of the trench in the TLPM as shown in FIG. 15A. Since the threshold voltage Vth of the TLPM is determined by an upper part of the trench (source side) where the concentration is relatively high, it is considered that the threshold voltage Vth is not vulnerable to any fixed electric charge generated at the bottom of the trench.

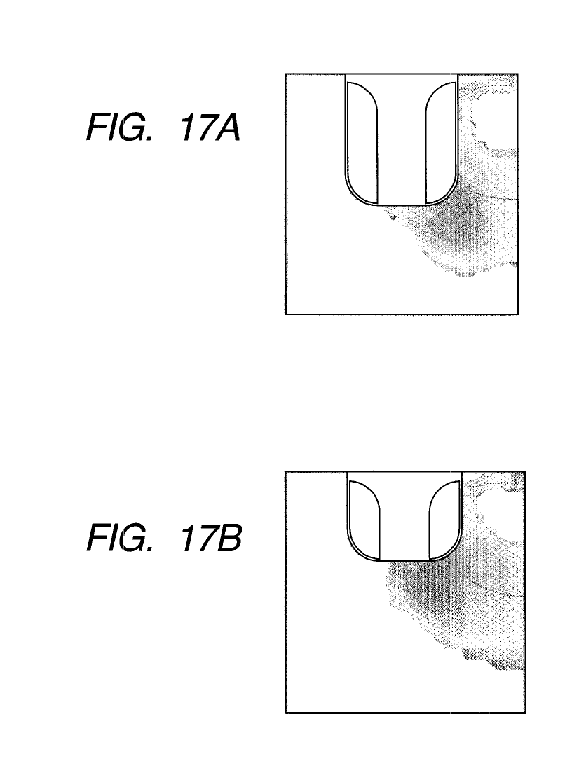

FIGS. 17A and 17B show distributions of impact ionization rates in the vicinity of the trench gate of the TLPM identified through simulations on devices having a gate voltage Vg of 2 V and a drain voltage Vd of 15 V carried out at a trench depth Dt of 1 μm (FIG. 17A) and a trench depth Dt of 0.7 μm (FIG. 17B). As shown in FIG. 17B, the impact ionization rate is high in a wide range near the surface of the drain region under the gate when the trench depth Dt is 0.7 μm. Therefore, fixed electric charges are generated in a wide range to hinder the flow of current in the on-state, which is considered to be the cause of reduction in the drain on current Ion.

As shown in FIG. 17A, the region of high impact ionization rates is a relatively small region located deep in the Si substrate in the vicinity of a corner of the bottom of the trench at the trench depth Dt of 1 μm. Therefore, the degradation of characteristics can be suppressed. However, even when the trench depth Dt is 0.7 μm as shown in FIG. 17B, it is considered that a low RonQg device satisfying the ratings for both of the on-state breakdown voltage and the hot carrier resistance can be provided by employing a structure in which a high electric field region can be formed deep in the substrate by optimizing the ion implanting condition for the n⁻ offset drain region. This presents one beneficial aspect of the present invention.

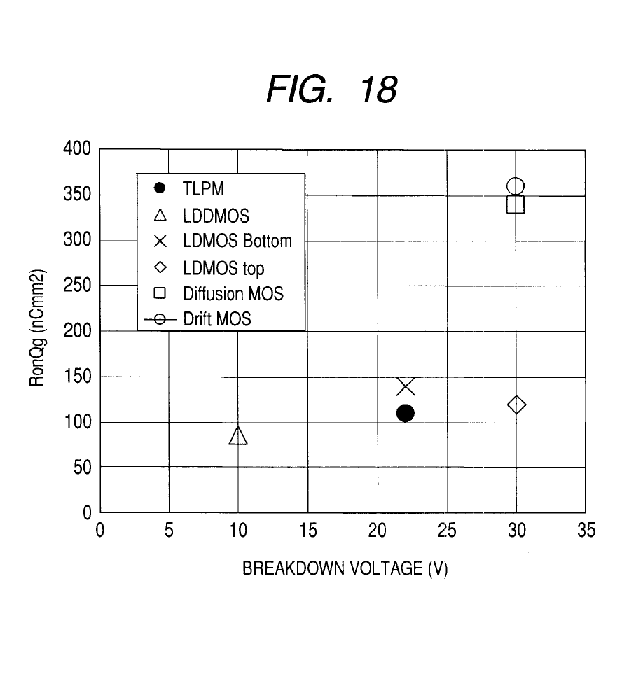

FIG. 18 shows the result of a comparison between gate charge characteristics RonQg of a planar device according to the related art having no trench gate and a trench gate type TLPM according to the invention. Since gate charge characteristics RonQg and a breakdown voltage are in a trade-off relationship, FIG. 18 shows a comparison between gate charge characteristics RonQg (ordinate axis), which are plotted relative to breakdown voltages (abscissa axis). In the case of the TLPM according to the invention, the trench makes it possible to achieve a low RonQg value while maintaining a preferable on-state breakdown voltage and hot carrier resistance. The TLPM according to the invention makes it possible to provide a reliable and efficient switching device operating at a high frequency. Specifically, the trench gate structure of the present TLPM allows efficient switching at a high frequency. Since the device can be fabricated with a small number of additional processing steps and can be optimized through the selection of a trench depth, it is advantageous in achieving the low on-resistance compared to planar devices.

When the trench is made shallower, the on-state breakdown voltage and hot carrier resistance become degraded, although the switching characteristics are improved. According to results of experiments and simulations, the reason has been identified to be the fact that a high electric field region spreads in the channel region. Therefore, variation of characteristics attributable to hot carriers can be suppressed by making the trench deeper to move the high electric field region deeper in the Si substrate. It has been also revealed that configuring the trench gate structure can make it possible to provide a TLPM that is more efficient, faster, and more reliable.

The present TLPM makes it possible to provide an insulated gate semiconductor device, i.e., a trench lateral MOSFET having improved hot carrier resistance without increasing the number of processes and the device pitch and without degrading the breakdown voltage characteristics and the on-resistance RonA characteristics. Specifically, the junction depth Xj of the p base region of the present TLPM is made smaller than the depth of the trench, and the trench can be formed with a depth Dt of about 1.2 μm such that the region does not contact a curved portion at the bottom of the trench. Thus, the TLPM device meets a rating of 15V for on- and off-state breakdown voltages and satisfies the requirement for a lower on-resistance RonA. Further, the n⁻ offset drain layer is formed to have a surface concentration Nd in the range from 1.0×10¹⁷/cm³ to 2.0×10¹⁷/cm³. Thus, the influence of the injection of hot carriers (electrons in this case) on the on-current can be suppressed at a point where the electric field concentrates, and the degradation of device characteristics (the degradation of a drain on-current Ion (μA) in this case) attributable to hot carriers can be dramatically mitigated.

The manufacturing method described herein can be implemented in other types of semiconductor devices without being limited to the embodiments or types described herein.

While the present invention has been particularly shown and described with reference to particular embodiments, it will be understood by those skilled in the art that the foregoing and other changes in form and details can be made therein without departing from the spirit and scope of the present invention. All modifications and equivalents attainable by one versed in the art from the present disclosure within the scope and spirit of the present invention are to be included as further embodiments of the present invention. The scope of the present invention accordingly is to be defined as set forth in the appended claims.

This application is based on, and claims priority to, JP PA 2006-315525, filed on 22 Nov. 2006. The disclosure of the priority application, in its entirety, including the drawings, claims, and the specification thereof, is incorporated herein by reference.

What is claimed is:

1. A semiconductor device comprising:
a semiconductor substrate of a first conductivity type;
a low concentration well layer of a second conductivity type on the substrate;
a trench formed in a main surface of the well layer and having sidewalls with at least one of the sidewalls having a substantially vertical portion that is substantially vertical to the main surface of the well layer and a curved corner portion extending from the substantially vertical portion and joining a bottom of the trench;
a gate electrode extending along the one sidewall of the trench with a gate oxide film interposed therebetween;
a base region of the first conductivity type in the well layer and providing a p-n junction with the well layer, wherein the base region is in contact with the gate oxide film on the one sidewall of the trench and an end of the p-n junction is positioned at the substantially vertical portion of the one sidewall, at a position shallower than the curved portion;
a source region of the second conductivity type on a main surface of the base region and in contact with the gate oxide film on the one sidewall of the trench;
a high concentration drain region of the second conductivity type in the well layer on the side of another sidewall of the trench opposite to the one sidewall of the trench,
wherein the well layer has a region having a surface concentration of at least 1.0×10¹⁷/cm³.

2. The semiconductor device according to claim 1, wherein the region having a surface concentration of at least 1.0×10¹⁷/cm³ comprises an offset drain region of the second conductivity type in the well layer at the bottom of the trench and spaced from the base region.

3. The semiconductor device according to claim 1, wherein the well layer is an epitaxial layer and the region having a surface concentration of at least 1.0×10¹⁷/cm³ comprises the epitaxial layer.

4. The semiconductor device according to claim 2, wherein the offset drain region has a surface concentration of no greater than 2.0×10¹⁷/cm³.

5. The semiconductor device according to claim 3, wherein the epitaxial has a surface concentration of no greater than 2.0×10¹⁷/cm³.

6. The semiconductor device according to claim 2, wherein the offset drain region and the high concentration drain region are connected.

7. The semiconductor device according to claim 4, wherein the offset drain region and the high concentration drain region are connected.

8. The semiconductor device according to claim 1, further comprising a field plate on the another sidewall of the trench with an oxide film interposed therebetween, and a drain electrode conductively connected to the high concentration drain region, wherein the field plate is conductively connected to the drain electrode.

9. The semiconductor device according to claim 4, further comprising a field plate on the another sidewall of the trench with an oxide film interposed therebetween, and a drain electrode conductively connected to the high concentration drain region, wherein the field plate is conductively connected to the drain electrode.

10. The semiconductor device according to claim 5, further comprising a field plate on the another sidewall of the trench with an oxide film interposed therebetween, and a drain electrode conductively connected to the high concentration drain region, wherein the field plate is conductively connected to the drain electrode.

11. The semiconductor device according to claim 7, further comprising a field plate on the another sidewall of the trench with an oxide film interposed therebetween, and a drain electrode conductively connected to the high concentration drain region, wherein the field plate is conductively connected to the drain electrode.

12. The semiconductor device according to claim 1, further comprising a source electrode conductively connected to the source region, and a high concentration region of the first conductivity on the main surface of the base region and in contact with the source region, and an insulation film embedded in the trench, wherein the source electrode also is conductively connected to the high concentration region of the first conductivity.

13. The semiconductor device according to claim 4, further comprising a source electrode conductively connected to the source region, and a high concentration region of the first conductivity on the main surface of the base region and in contact with the source region, and an insulation film embedded in the trench, wherein the source electrode also is conductively connected to the high concentration region of the first conductivity.

14. The semiconductor device according to claim 5, further comprising a source electrode conductively connected to the source region, and a high concentration region of the first conductivity on the main surface of the base region and in contact with the source region, and an insulation film embedded in the trench, wherein the source electrode also is conductively connected to the high concentration region of the first conductivity.

15. The semiconductor device according to claim 7, further comprising a source electrode conductively connected to the source region, and a high concentration region of the first conductivity on the main surface of the base region and in contact with the source region, and an insulation film embedded in the trench, wherein the source electrode also is conductively connected to the high concentration region of the first conductivity.

16. The semiconductor device according to claim 8, further comprising a source electrode conductively connected to the source region, and a high concentration region of the first conductivity on the main surface of the base region and in contact with the source region, and an insulation film embedded in the trench, wherein the source electrode also is conductively connected to the high concentration region of the first conductivity.

17. A method of manufacturing a semiconductor device, comprising the steps of:
providing a semiconductor substrate of a first conductivity type;
forming a low concentration well layer of a second conductivity type on the substrate;
forming a trench in a main surface of the well layer so that the trench has sidewalls with at least one of the sidewalls having a substantially vertical portion that is substantially vertical to the main surface of the well layer and a curved corner portion extending from the substantially vertical portion and joining a bottom of the trench;
forming a gate electrode extending along the one sidewall of the trench with a gate oxide film interposed therebetween;
forming a base region of the first conductivity type in the well layer to form a p-n junction with the well layer, and so that the base region is in contact with the gate oxide film on the one sidewall of the trench and an end of the p-n junction is positioned at the substantially vertical portion of the one sidewall, at a positioned shallower than the curved portion;
forming a source region of the second conductivity type on a main surface of the base region and in contact with the gate oxide film on the one sidewall of the trench; and
forming a high concentration drain region of the second conductivity type in the well layer on the side of another sidewall of the trench opposite to the one sidewall of the trench,
wherein the well layer has a region having a surface concentration of at least 1.0×10¹⁷/cm³.

18. The method according to claim 17, further comprising the step of forming an offset drain region of the second conductivity type in the well layer at the bottom of the trench and spaced from the base region, wherein the offset drain region is the region having a surface concentration of at least 1.0×10¹⁷/cm³.

19. The method according to claim 17, wherein the well layer is an epitaxial layer and the region having a surface concentration of at least 1.0×10¹⁷/cm³ comprises the epitaxial layer.

20. The method according to claim 18, wherein the offset drain region has a surface concentration no greater than 2.0×10¹⁷/cm³.

21. The method according to claim 19, wherein the epitaxial layer has a surface concentration no greater than 2.0×10¹⁷/cm³.
